(19) United States
(12) Patent Application Publication
(10) Pub. No.: US 2026/0010680 A1
(43) Pub. Date: Jan. 8, 2026

(54) TRAINED COMPUTERIZED MODEL FOR STRUCTURED DATA

(71) Applicant: SAP SE, Walldorf (DE)

(72) Inventors: Marco Spinaci, Versailles (FR); Sam Thelin, Stuttgart (DE); Clemens Biehl, Frankfurt (DE); Matthias Frank, Heidelberg (DE); Markus Kohler, Pfinztal (DE); Johannes Hoffart, Frankfurt (DE); Margarida Costa, Munich (DE); Michael Medek, Heidelberg (DE)

(21) Appl. No.: 18/828,329

(22) Filed: Sep. 9, 2024

Related U.S. Application Data
(60) Provisional application No. 63/666,927, filed on Jul. 2, 2024.

(51) Int. Cl. G06F 30/27; G06F 16/21

(52) U.S. Cl. CPC G06F 30/27; G06F 16/21

(57) ABSTRACT

Various examples are directed to systems and methods of using a computerized model. A training system may access training data comprising a plurality of tables. A first table of the plurality of tables may comprise a plurality of records and a first record of the plurality of records may comprise a first plurality of cells. The training system may tokenize the first plurality of cells to generate a first tokenized record comprising a first plurality of cell vectors. The training system may mask a masked portion of the first plurality of cell vectors to generate a first masked tokenized record. The training system may execute the computerized model using the first masked, tokenized record to generate a prediction of the masked portion of the first plurality of cells. The training system may determine an error based at least in part on the prediction of the masked portion of the first plurality of cells and modify the computerized model based on the error.

### PRIORITY

This application claims the benefit of U.S. Provisional Patent Application Ser. No. 63/666,927 filed on Jul. 2, 2024, which is incorporated herein by reference in its entirety.

### BACKGROUND

Software applications, including enterprise resource planning (ERP) applications, store and operate on data, including structured data. Software applications may utilize the structured data to perform various analyses and provide results of the analyses to users.

### BRIEF DESCRIPTION OF DRAWINGS

The present disclosure is illustrated by way of example and not limitation in the following appendices and figures.

FIG. 1 is a diagram showing one example of an environment for using a computerized model on structured data.

FIG. 2 is a flowchart showing one example of a process flow that may be executed by the training system of FIG. 1 to train the computerized model of FIG. 1.

FIG. 3 is a flowchart showing one example of a process flow that may be executed by the training system of FIG. 1 to tokenize a record.

FIG. 4 is a flowchart showing one example of a process flow that may be executed by the training system of FIG. 1 to tokenize text data from a cell of a record.

FIG. 5 is a flowchart showing one example of a process flow that may be executed by the training system of FIG. 1 to tokenize timestamp data from a cell of a record.

FIG. 6 is a flowchart showing one example of a process flow that may be executed by the training system of FIG. 1 to tokenize numerical data from a cell of a record.

FIG. 7 is a flowchart showing one example of a process flow that may be executed by the training system of FIG. 1 to train the computerized model of FIG. 1 using more than one tokenized record at a time.

FIG. 8 is a flowchart showing one example of a process flow that may be executed by the database management application of FIG. 1 to respond to a query using the computerized model of FIG. 1.

FIG. 9 is a block diagram showing one example of an architecture for a computing device.

FIG. 10 is a block diagram of a machine in the example form of a computer system within which instructions may be executed for causing the machine to perform any one or more of the methodologies discussed herein.

### DETAILED DESCRIPTION

A database management application can be implemented as part of a suite of software applications that execute together. For example, the database management application may support various client processes that utilize the database management application to manage data. In some examples, a database management application is implemented with a suite of processes that implement one or more enterprise resource planning (ERP) software applications. ERP applications are often used in conjunction with a database management application to manage various aspects of business operations. An example ERP software application is the S/4 HANA product available from SAP SE of Walldorf, Germany.

The ERP application generates and utilizes the data stored by the database management application to perform different enterprise operations. For example, an ERP application supporting a human resources operation may store employee records at the database management application. An ERP application supporting accounting may use records managed by the database management application to perform various accounting-related tasks such as generating and recording invoices, purchase orders, and the like. An ERP application supporting human resources management may perform various tasks related to, for example, using data managed by the database management application to generate and manage payroll, benefits, and the like. Other ERP applications may perform other business tasks.

The database management application may store ERP application data in a structured manner. For example, the database management application may implement a data schema including multiple tables. Each table stores data in logical rows and columns. The data stored at a row of a table may be referred to as a record. A record may comprise multiple cells, where each cell corresponds to a column of the table. Consider the example of TABLE 1 below, describing purchase orders associated with a manufacturing facility:

TABLE 1

| Order # | Material | Cost | Delivery Date |
|---|---|---|---|
| A1 | Copper | $2,344.23 | May 16, 2024 |
| A2 | Oil | $834.71 | Mar. 18, 2024 |
| A3 | Brackets | $984.73 | — |
| . . . | . . . | . . . | . . . |
| AN | Forklift | $25,987.54 | Aug. 3, 2024 |

TABLE 1 includes columns labeled Order #, Material, Cost, and Delivery Date. Each record at TABLE 1 includes a cell corresponding to each of the columns. Accordingly, each record in TABLE 1 has a cell indicating Order #, a cell indicating Material, a cell indicating Cost, and a cell indicating Delivery Date. Although the example TABLE 1 comprises four rows and four columns, it will be appreciated that various tables managed by a database management application may include more or fewer rows and more or fewer columns.

The example TABLE 1 also illustrates different data types. For example, values of cells corresponding to the column Material may be text data comprising one or more text strings. Values of cells corresponding to the column Cost may be numerical data having a numerical value. Values of cells corresponding to the column Delivery Date may be dates. Also, as illustrated by the example TABLE 1, cells of a record may be filled or empty. A cell of a record is filled if there is data stored at the associated cell. In the example TABLE 1, the cell indicating the delivery date of the record for Order #A3 is empty. Other cells of the records A1, A2, and AN are filled. In some examples, this may be because the Order #A3 has not yet been delivered.

Various examples described herein utilize computerized models to extract information from data stored by the database management application. Consider the example of TABLE 1. In some examples, a computerized model may be utilized to predict a value for the empty Delivery Date field of the Order #A3 record. This may allow a customer enterprise utilizing the ERP application and database management application to perform more accurate forecasting. There are many similar situations where it may be desirable to predict values for one or more additional empty cells in a database management application managing one or more ERP applications.

Transformer models, used in many Large Language Models (LLM), can be highly effective at generating predictions of missing data in a large data set. Applying a transformer model to the structured data of a database management application, however, may present challenges. For example, structured data in a database is not ordered in the same way as natural language. In natural language, words are represented in a particular order, and the order of the words is relevant to the meaning of the phrase. Many transformer models exploit the ordered nature of natural language when generating predictions of missing data. In a database record, on the other hand, the order of cells in a record is not often relevant to the meaning of the cell values. For example, reordering the columns of the example TABLE 1 would not change the meaning of the data in any of the corresponding cells. Because many transformer models rely on positional encoding to extract information from input data, the unordered nature of structured data may compromise the effectiveness of the model.

Another challenge is that, while natural language contains almost exclusively words, database records may contain different types of data. For example, database records supporting an ERP application may include cells for text data, timestamp data, and numerical data, as described herein. Transformer models designed for operating on text data only may not be suitable for operating on mixed data of this type.

Various examples address these and other challenges utilizing a trained computerized model that is trained to operate on structured data such as, for example, structured data stored by a database management application for one or more ERP applications. The training system may train the computerized model based on training data. The training data may comprise one or more tables comprising records including structured data.

The training system may tokenize the training data. Tokenizing the training data may include converting records into sets of cell vectors. For example, a record managed by a database management application may be tokenized by determining a cell vector for each filled cell of the record. The cell vector for a cell may be based on the content of the cell and, in some examples, other data such as the column associated with the cell. For example, a content vector for a cell may be determined based on the content of the cell. In some examples, the content vector is the cell vector. In other examples, the content vector is combined with a column name vector to generate the cell vector. A tokenized record may include the cell vectors corresponding to each filled cell of the record. In some examples, the content vector for a cell may also be combined with other data describing the cell such as, for example, the size of the data in the cell with respect to other cells in the same column.

Content vectors for different types of data may be determined using different techniques. For example, a content vector corresponding to text data may be found by executing a pre-trained computerized model. The pre-trained computerized model may receive the text data as input and generate a corresponding content vector as output. In some examples, a content vector corresponding to timestamp data may be determined by formatting the timestamp data. For example, timestamp data may be formatted to include numerical values for the day, month, and year indicated by the timestamp data. In some examples, timestamp data may indicate a time of day the time of day it may also be expressed, for example, in terms of an hour, a minute, or smaller units if desired. The content vector may be based on a combination of the day, date, year, and any other expressions of the time stamp. In some examples metadata describing a particular date may also be incorporated into the content vector. A content vector for numerical data may be determined, for example, by expressing the numerical data in exponent form. In some examples, this includes expressing the numerical data as a factor, an exponent, and a sign. The factor, exponent, and sign may be combined (e.g., using addition, multiplication concatenation, or other suitable operations) to generate a content vector.

In some examples, a cell vector also considers the column associated with the cell. For example, a column name may be tokenized to generate a column name vector. In some examples, the column name is tokenized in a manner similar to other text data. The column name vector for a cell may be combined with the content vector of the cell to generate the cell vector. Any suitable combination may be used such as: addition, multiplication, concatenation, and/or the like. Considering the column associated with the cell one tokenizing a record, in some examples, improves the performance of the computerized model when operating on structured data that, as described herein, may not have a meaningful sequence.

The training system may utilize tokenized training data to train the computerized model. The training system may receive a tokenized record and mask the tokenized record to generate a masked tokenized record. Masking a tokenized record may include removing or otherwise masking cell vectors from one or more cells of the tokenized record. Masking the cell vectors may include setting the value of the masked cells to null, zero, or another value recognizable by the computerized model as not including a cell vector.

The training system may execute the computerized model with the masked tokenized record as input. The output of the computerized model may include a prediction of the set of cell vectors that were masked in the masked tokenized record. The training system may generate an error by comparing the predicted cell vectors to the values of the masked cell vectors that were previously removed from the masked tokenized record. The determined error may be used to modify the computerized model, for example, by modifying one or more coefficients of the computerized model.

The training system may repeat this process over multiple records from the training data to train the model. In some examples, each processing of a training data record constitutes a single training epoch for the computerized model. In other examples, the training epochs may include the processing of multiple tokenized records, such as multiple tokenized records from the same table. At the conclusion of a suitable number of training epochs, the computerized model may be trained. The trained computerized model may then be used, for example, by the database management application, to respond to queries from users of one or more ERP applications. In this way, the computerized model may be arranged to process structured data, for example, as described herein.

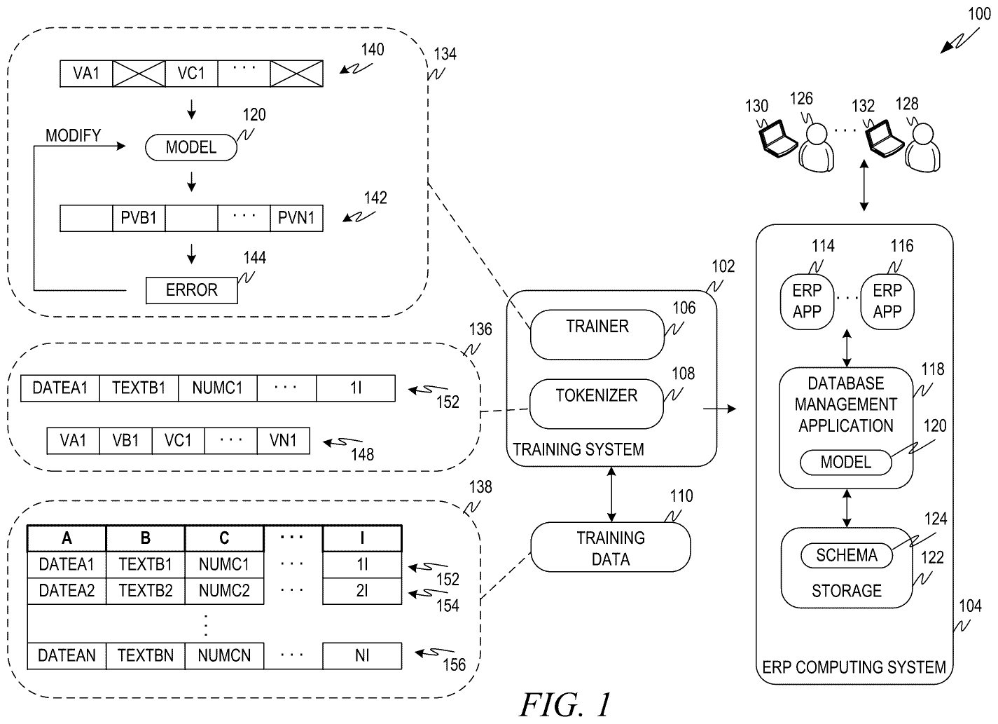

FIG. 1 is a diagram showing one example of an environment 100 for using a computerized model 120 on structured data such as, for example, data managed by a database management application 118 for one or more ERP applications 114, 116. The environment 100 comprises an ERP computing system 104 and a training system 102. The ERP computing system 104 executes a database management application 118 that may use the computerized model 120 to respond to queries. The training system 102 may be configured to train the computerized model 120 and provide the computerized model 120 to the ERP computing system 104 after training.

The computerized model 120 may be of any suitable computerized model type. In some examples, the computerized model 120 is arranged as a transformer model. In some examples, the computerized model may comprise an autoencoder model including an encoder model and a decoder model. The encoder and decoder models may be neural networks such as, for example, long short-term memory (LSTM) neural networks. The encoder model is configured to map inputs to continuous representations. The continuous representations generated by the encoder model are provided to the decoder model. The decoder model operates on the output of the encoder model and on previous outputs of the decoder model to generate a prediction of missing or empty cell values based on the input to the computerized model 120. The encoder and decoder models may be configured to implement one or more self-attention mechanisms. In some examples, the computerized model 120 may be configured to omit positional encoding. In this way, the computerized model 120 may be configured to disregard the order of cell vectors provided as input to the model 120. In some examples, the computerized model may comprise only an encoder model, or only a decoder model

The ERP computing system 104 may execute one or more ERP applications 114, 116 on behalf of users 126, 128. The ERP computing system 104 may also execute a database management application 118 that may be in communication with a persistent storage 122. The persistent storage 122 may store structured data, making up a database managed by the database management application 118. In some examples, the data at the persistent storage 122 may be arranged according to a schema 124. The schema 124 may define various tables and relationships there between. The tables may comprise records, as described herein.

The ERP applications 114, 116 may be or include any suitable ERP application such as, for example, an operations management application, a human resources application, an accounting application, and/or the like. Example ERP applications include SAP S/4HANA Cloud analytics software solutions such as the SAP® Analytics Cloud application available from SAP SE of Walldorf, Germany, a human capital management software solution such as SAP SuccessFactors®, also available from SAP SE of Walldorf, Germany, a project management software solution such as SAP Portfolio and Project Management (PaPM), also available from SAP SE of Walldorf, Germany.

Users 126, 128 may access the ERP computing system 104 to use the ERP applications 114, 116. In some examples, users 126, 128 access the ERP computing system 104 with user computing devices 130, 132. The user computing devices 130, 132 may be or include any suitable computing device such as a mobile computing device, a laptop computing device, a desktop computing device, and/or the like.

The ERP computing system 104 may be implemented in an on-premise and/or in a cloud environment. When the ERP computing system 104 is implemented in an on-premise environment, a customer enterprise may obtain software for executing the ERP applications 114, 116, and the database management application 118 from a software provider enterprise. The customer enterprise may maintain computer hardware for implementing the ERP computing system 104, for example, on the customer enterprise's own premises.

In a cloud environment, a hyperscaler or other cloud service provider provides computing hardware for executing the ERP applications 114, 116 and database management application 118 and implementing persistent storage 122. Users 126, 128 access the ERP applications 114, 116 and database management application 118 at the provided computing hardware, which may be referred to as a cloud environment.

A cloud environment may be a public cloud environment or a private cloud environment. In a private cloud environment, the customer enterprise may provide executables and other files to implement the ERP applications 114, 116 and database management application 118 to the cloud service provider. In a public cloud environment, users associated with the customer enterprise are provided with access to the ERP system 104 through one of a number of tenancies. The software provider enterprise may provide executables and other files to implement the ERP system 104 and, in some examples, may also maintain the ERP computing system 104 and the various tenancies. For example, users 126, 128 may be associated with one customer enterprise having a first tenancy at a public cloud environment. The users 126, 128 may have access to the ERP applications 114, 116 and database management application 118. Other users associated with other customer enterprises holding other tenancies may have access to other instances of the ERP applications 114, 116 also executing at the public cloud environment.

The training system 102 may comprise a trainer 106 and the tokenizer 108. The trainer 106 and tokenizer 108 may be or include software that is executed at the training system 102 to implement tokenizing of training data 110 and training of the computerized model 120. The training system 102 may also be executed in an on-premise arrangement or in a cloud environment. In some examples, the training system 102 is executed in the same cloud environment as the ERP computing system 104. For example, the training system 102 may execute at a tenancy of a public cloud environment associated with the software provider enterprise. The ERP computing system 104 may be executed in another tenancy of the public cloud environment.

In the example of FIG. 1, the tokenizer 108 uses training data 110 to generate tokenized records. The training data 110 may be any suitable quantity of structured data that is accessible to the training system 102. In some examples, the training data 110 includes tables that are part of the schema 124 implemented by the database management application 118. For example, the training system 102 may be in communication with the ERP computing system 104 to obtain structured data managed by the database management application 118 for use as training data 110.

The window 138 shows an example table that may be used as training data. The example table at window 138 comprises columns A, B, C, . . . . I. Each row of the example table is a record, where the record comprises a cell corresponding to each of the columns. Three example records 152, 154, 156 are shown in FIG. 1. In this example, cells corresponding to the column A comprise timestamp data; cells corresponding to the column B comprise text data, and cells corresponding to column C comprise numerical data.

A window 136 shows an example tokenizing operation performed by the tokenizer 108 on the record 152. During tokenization, the value at each cell is converted to a corresponding cell vector. In some examples, the cell vector may be based on a content vector determined from a content of the corresponding cell and a column of vector determined from a column name corresponding to the cell. A tokenized record 148 has a similar structure to the record 152 (e.g., the same number of cells), but the cell values of the record 152 are replaced with corresponding cell vectors.

The tokenizer 108 is configured to tokenize different types of data differently. For example, the tokenizer 108 may generate a content vector for text data, such as the cell value TEXTB1 from the record 152, by providing the text data as input to a pre-trained model. The pre-trained model may be any suitable model that is configured to embed text data to generate a corresponding cell vector representing the text data. The pre-trained model may generate a content vector as output. The pre-trained model may be or include any suitable text in betting model such as, for example, various text embedding models available from Hugging Face, Inc.

The tokenizer 108 may generate a content vector from timestamp data, such as DATEA1 from the record 152, at least in part, by expressing the timestamp data in a vector format including a numerical representation of the day, the month, and the year of the date. For example, the day may be represented as a number between 1 and 31, indicating the day of the month. The month may be represented by a number between 1 and 12 indicating the month of the year. The year may be represented by a number of a selected range of years. For example, a range of years encompassing all of years that are likely to be represented in the considered data may be selected. One example of such a range may be between 1950 and 2100. In this example, dates in 1950 would be represented by 1, dates in 1951 would be represented by 2, and so on. The tokenizer 108 may combine the numerical representations of the day, the month, and the year of the timestamp data to generate a content vector representing a date. The tokenizer 108 may combine the numerical representations of the day, the month, and to the year in any suitable manner including, for example, using operations such as addition, multiplication, concatenation, and/or the like.

In some examples, the tokenizer 108 is also configured to consider date metadata when generating a content vector representing timestamp data. Date metadata may indicate the status of a particular date. Example statuses of a date may include: a day of the week associated with the date, whether the date was a weekday or a weekend, whether the date was a holiday, and/or the like. Information about whether the date was a holiday may also include information describing jurisdictions where the date was a holiday. For example, date metadata for the date Jul. 4, 2024 may indicate that the date fell on the holiday of Independence Day in the United States. The tokenizer 108 may be configured to include date metadata in the content vector, representing a date in any suitable manner. In some examples, the date metadata may be converted to a date metadata vector, for example, using a trained computerized model in a manner similar to that described above with respect to the tokenization of text data. The date metadata vector may be added to the vector format representation of the timestamp data using any suitable operations such as addition, multiplication, concatenation, and/or the like.

The tokenizer 108 may generate a content vector for numerical data, such as NUMC1 from the record 152, by expressing the value of the numerical data as a factor, an exponent, and a sign. In some examples, numerical data is expressed in scientific notation as a factor of a power of 2. Consider example numerical data having a value of 24. The tokenizer 108 may find a closest power of 2. In the case of 24, the closest power of 2 is 16, which is 2\hat{ }4. Accordingly, the factor would be 1.5, and the exponent would be 4 (E.g. 24=1.5×2\hat{ }4). In some examples, an additional Boolean value may be added to indicate whether the numerical value is negative or positive. The tokenizer 108 may generate the content vector for the numerical value by combining the factor, exponent, and the sign any suitable operations such as addition, multiplication, concatenation, and/or the like. In some examples, prior to combination, the factor, exponent, and sign may be embedded, for example, by multiplying them with a learnable vector.

In some examples, the tokenizer 108 may set the cell vector for a cell equal to the content vector determined as described herein. In other examples, the tokenizer 108 may determine a cell vector for a cell by combining the corresponding content vector with a column vector describing the column associated with the cell. The tokenizer 108 may generate the cell vector, for example, by processing the name of the column as text data. This may involve, for example, executing the pre-trained model using the name of the column as input. The column vector may be based on the output of the pre-trained model. The trainer 106 may combine the content vector for a cell and the column vector for a cell using any suitable operations such as addition, multiplication, concatenation, and/or the like.

The trainer 106 may utilize tokenized records generated by the tokenizer 108 to train the computerized model 120. The trainer 106 may receive a tokenized record and masked the tokenized record. Masking the tokenized record may comprise masking one or more cell vectors of the tokenized record to generate a masked tokenized record. Masking a cell of a tokenized record may include removing the corresponding cell vector from the tokenized record. The cell vector for a masked cell may be replaced with data indicating, for example, null, zero, or another suitable value recognized by the computerized model 120 as indicating that a cell vector has been masked.

The number and identity of masked cell vectors may be determined in any suitable manner. In some examples, the number of masked cells may be selected as a configurable parameter of the trainer 106. For example, a single cell may be masked. In some examples, between about 10% and about 80% of the cells in a tokenized record may be masked. The particular cells for masking may be selected randomly. For example, the trainer 106 may execute a suitable random or pseudorandom algorithm to select the particular cells/cell vectors to be masked.

The trainer 106 may execute the computerized model 120 using one or more masked tokenized records as input. The output of the computerized model 120 may include a prediction of the set of one or more masked cell vectors. The prediction may include a predicted cell vector corresponding to each of the set of one or more masked cell vectors. The trainer 106 may be configured to compare the predicted cell vectors to the actual value of the masked cell vector or vectors from the tokenized record. The difference between the predicted cell vector or vectors generated by the computerized model 120 and the actual values of the masked cell vector or vectors from the tokenized record may be used to generate an error. The error may be used to modify the computerized model 120. The trainer 106 may be configured to repeat the process of providing masked tokenized records to the computerized model 120 a suitable number of times so as to train the computerized model 120.

In some examples, the trainer 106 may determine the error considering the data type of the corresponding cells. For example, the error between a predicted cell vector and a masked cell vector indicating text data may be based on a Euclidean distance between the two vectors, a negative cosine similarity between the two vectors, or other suitable measure. The error between a predicted cell vector and a masked cell vector indicating timestamp data may be based on individual distances between vectors representing the day, the month, and the year. A total error may be determined, in some examples, by finding a cross entropy loss.

Similarly, the error between a predicted cell vector and a masked cell vector indicating numerical data may be based on individual Euclidean or other distances between vectors representing the factor, the exponent, and the sign. In some examples, the values may be binned, with cross-entropy loss applied to the result. For example, a predicted cell vector may be considered to match a masked cell vector if it falls in the same bin as the masked cell vector and may be considered a miss otherwise. A total error may similarly be determined by finding a cross entropy loss or other similar suitable mechanism.

In some examples, the computerized model 120 is configured to generate multiple predicted cell vectors for each masked cell vector. For example, for each masked cell vector, the computerized model 120 may generate a predicted cell vector of each considered data type. For example, the computerized model may generate a predicted text cell vector based on text data, a predicted date cell vector based on timestamp data, and a predicted numerical cell vector based on numerical data. In some examples, the trainer 106 is configured to select the predicted cell vector corresponding to a correct data type of the masked cell vector, as indicated by the column of the cell. The error may be generated based on the difference between the masked cell vector and the predicted cell vector of the correct data type.

The breakout window 134 shows an example operation of the trainer 106. For example, starting from the tokenized record 148, the trainer 106 may generate masked tokenized record 140. In this example, the trainer 106 masks the cell vector VB1 and VN1. The trainer 106 executes the computerized model 120 using the masked tokenized record 140 as input. The result is a prediction 142 of the masked cell vectors. In this example, the output of the computerized model 120 includes a prediction vector PVB1 corresponding to the cell vector VB1 and a prediction vector PVN1 corresponding to the cell vector VN1. Trainer 106 may determine an error 144 based on the differences between the prediction of the masked cell vectors (e.g., PVB1, PVN1) and the actual values of the masked cell vectors indicated by the tokenized record (e.g., VB1, VN1). In some examples, this may include determining a cross entropy loss based on a probability distribution among all possible values of the respective vectors. Based on the error 144, modifications may be made to the computerized model 120.

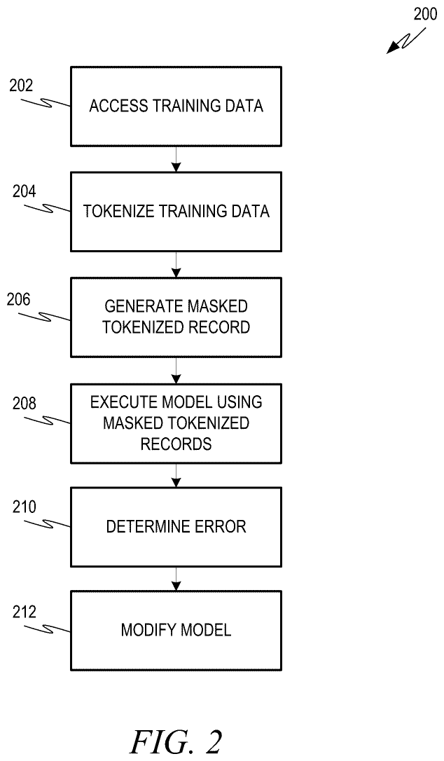

FIG. 2 is a flowchart showing one example of a process flow 200 that may be executed by the training system 102 of FIG. 1 to train the computerized model 120 of FIG. 1. At operation 202, the training system 102 may access training data. At operation 204, the training system 102 may tokenize the training data to generate tokenized records. At operation 206, the training system 102 may mask one or more of the tokenized records to generate masked tokenized records.

At operation 208, the training system 102 may execute the computerized model 120 using one or more of the masked tokenized records as input. The result may be a prediction of the set of cell vectors that were masked. At operation 210, the training system 102 may determine an error based on the prediction of the masked error vectors and the actual value of the masked error vectors from the tokenized record. At operation 212, the training system 102 may modify the computerized model based on the determined error. The training system 102 may be configured to reexecute the process flow 200 for multiple different tokenized records. Any suitable number of tokenized records may be considered. After a suitable number of tokenized records have been considered, the computerized model 120 may be trained.

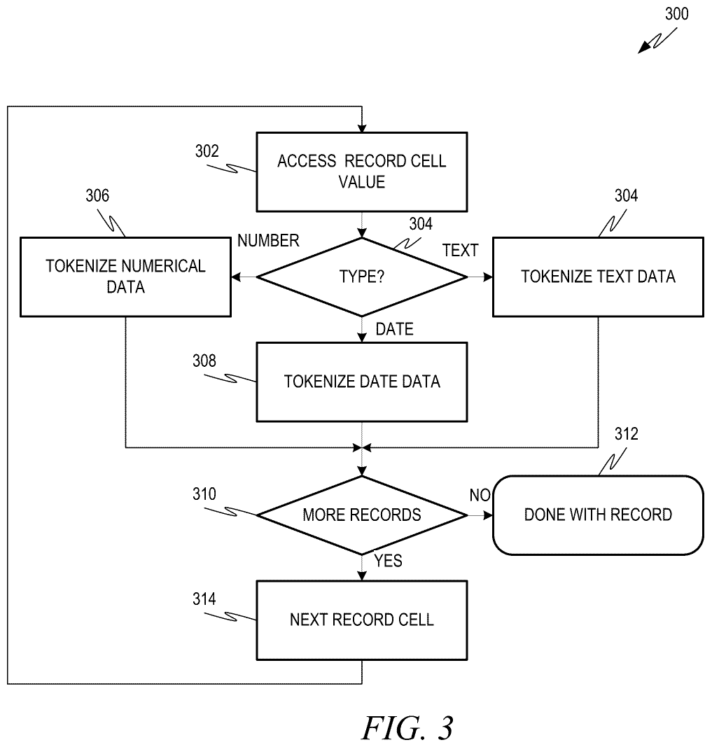

FIG. 3 is a flowchart showing one example of a process flow 300 that may be executed by the training system 102 of FIG. 1 (e.g., the tokenizer 108 of FIG. 1 thereof) to tokenize a record. At operation 302, the training system may access a cell value from a record. At operation 304, the training system 102 may determine a type of data in the cell. If the type of data is text data, then the training system 102 (e.g., the tokenizer 108 thereof) may tokenize the value of the text data at operation 304 to generate a cell vector. If the type of data is numerical data, then the training system 102 (e.g., the tokenizer 108 thereof) may tokenize the numerical data at operation 306 to generate a cell vector. If the type of data is timestamp data, then the training system 102 (e.g., the tokenizer 108 thereof) may tokenize the timestamp data at operation 308 to generate a cell vector. After tokenizing the data at one of operations 304, 306, or 308, the training system 102 may determine, at operation 310, whether there are any additional cells in the considered record. If there are additional cells in the considered record, then the training system 102 may consider the next cell of the record at operation 314 and return to operation 302. If there are no additional cells in the record, then the training system 102 may complete tokenization of the record at operation 312. In some examples, the training system 102 may tokenize other records, as described herein.

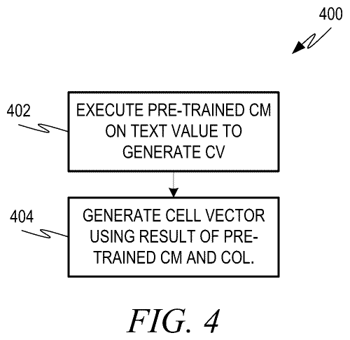

FIG. 4 is a flowchart showing one example of a process flow 400 that may be executed by the training system 102 of FIG. 1 (e.g., the tokenizer 108 of FIG. 1 thereof) to tokenize text data from a cell of a record. The process flow 400 illustrates one example way of executing the operation 304 of the process flow 300. At operation 402, the training system 102 (e.g., the tokenizer 108 thereof) may execute a pre-trained computerized model providing the text data as input. The output of the model may comprise a content vector describing the text data.

At operation 404 the training system 102 (e.g., the tokenizer 108 thereof) may generate the cell vector using the content vector and an indication of the column corresponding to the cell. In some examples, the column name is also vector embedded to generate a column vector, for example, as described herein. The content vector and a column vector may be combined using any suitable operation such as, for example, addition, multiplication, concatenation, and/or the like.

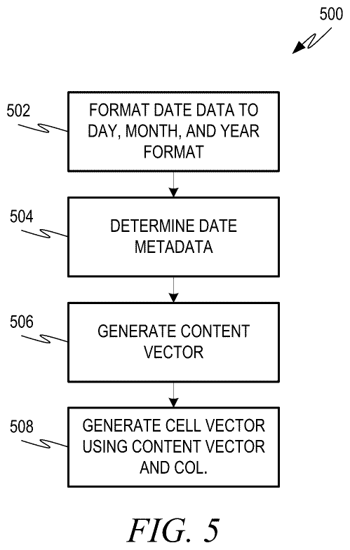

FIG. 5 is a flowchart showing one example of a process flow 500 that may be executed by the training system 102 of FIG. 1 (e.g., the tokenizer 108 of FIG. 1 thereof) to tokenize timestamp data from a cell of a record. The process flow 500 shows one example way of executing the operation 308 of the process flow 300. At operation 502, the training system 102 (e.g., the tokenizer 108 thereof) may format or encode the timestamp data with a numerical value for the day, month, and year of the associated date. At operation 504, the training system 102 (e.g., the tokenizer 108 thereof) may determine date metadata associated with the date. In some examples, the date metadata comprise a number of Booleans such as, for example, a holiday Boolean for each country or other jurisdiction. The holiday Boolean may have a value corresponding to true if the day is a holiday in the corresponding jurisdiction and a value corresponding to false if it is not.

At operation 506, the training system 102 (e.g., the tokenizer 108 thereof) may generate a content vector using the day, month, and year format of the date and the date metadata. At operation 508, the training system 102 (e.g., the tokenizer 108 thereof) may generate a cell vector using the content vector and an indication of the column corresponding to the cell. For example, the content vector and a column vector may be combined using addition, multiplication, concatenation, and/or the like. In some examples, the operation 506 may be omitted. The day, month, and year expression of the timestamp data, the vector embedding of the date metadata, and the column vector may be combined in a single operation using addition, multiplication, concatenation, and/or the like.

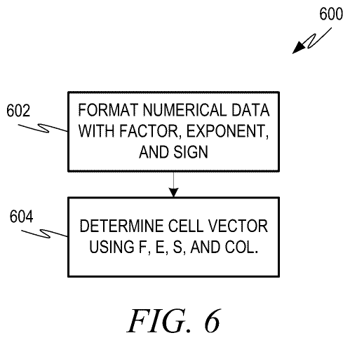

FIG. 6 is a flowchart showing one example of a process flow 600 that may be executed by the training system 102 of FIG. 1 (e.g., the tokenizer 108 of FIG. 1 thereof) to tokenize numerical data from a cell of a record. The process flow 600 shows one example way of executing the operation 306 of FIG. 3 of the process flow 300 of FIG. 3. At operation 602, the training system 102 (e.g., the tokenizer 108 thereof) may generate a content vector from the numerical data, for example, by expressing the numerical data as a factor, exponent, and sign. In some examples, the exponent is the power of two nearest to the numerical data value. The factor is the number of times that the numerical data can be divided into the nearest power of two, and the sign indicates whether the numerical data is positive or negative. At operation 604, the training system 102 of FIG. 1 (e.g., the tokenizer 108 of FIG. 1 thereof) may generate a cell vector using the content vector and a column vector, which may be a vector embedding of the column name. For example, the content vector and column vector may be combined using addition, multiplication, concatenation, and/or the like.

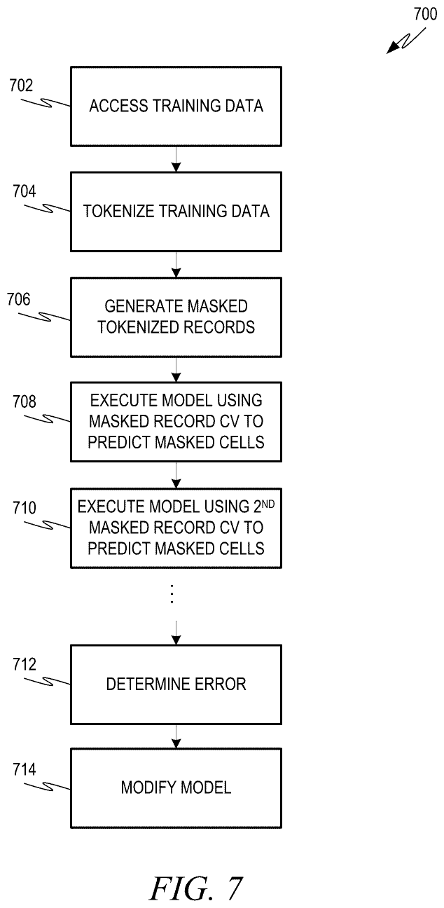

FIG. 7 is a flowchart showing one example of a process flow 700 that may be executed by the training system 102 of FIG. 1 to train the computerized model 120 of FIG. 1 using more than one tokenized record at a time. In some examples, different tokenized records used to train the computerized model 120 may come from the same table or from different tables. At operation 702, the training system 102 may access training data. At operation 704, the training system 102 may tokenize the training data to generate tokenized records.

At operation 706, the training system 102 (e.g. the tokenizer 108 thereof) may generate multiple masked tokenized records. For example, the training system 102 may mask a first tokenized record to generate a first masked tokenized record. The training system 102 may then identify additional tokenized records. The additional tokenized records may have the same cell values (and therefore the same cell vectors) for the masked cells as the first tokenized record and/or may have different cell values (and therefore different cell vectors). The additional tokenized records may be masked, with the same cells masked as were selected to be masked for the first tokenized record.

At operation 708, the training system 102 of FIG. 1 (e.g., the trainer 106 of FIG. 1 thereof) may execute the computerized model 120 using the first masked tokenized record as input. The result may be a first prediction of the set of one or more masked cell vectors from the masked tokenized record. At operation 710, the training system 102 may execute the computerized model again using an additional masked tokenized record generated at operation 706. The result may be a second prediction of the set of one or more masked cell vectors predicated on the contents of the additional record. If there are more additional masked tokenized records, then the training system 102 may execute the computerized model 120 more times, once for each of the additional masked tokenized records.

At operation 712, the training system 102 (e.g., the trainer 106 thereof) may determine an error based on the predictions of the set of masked cell vectors generated over the different executions of the computerized model 120. In some examples, an average of the error over the different executions of the computerized model 120 may be used. Also, in some examples, additional masked tokenized records based on records having different values of the masked cells may be weighted in the error so as to train the computerized model 120 away from incorrect values of the masked cell vectors. At operation 714, the training system 102 (e.g., the trainer 106 thereof) may modify the computerized model 120 based on the error determined at operation 712.

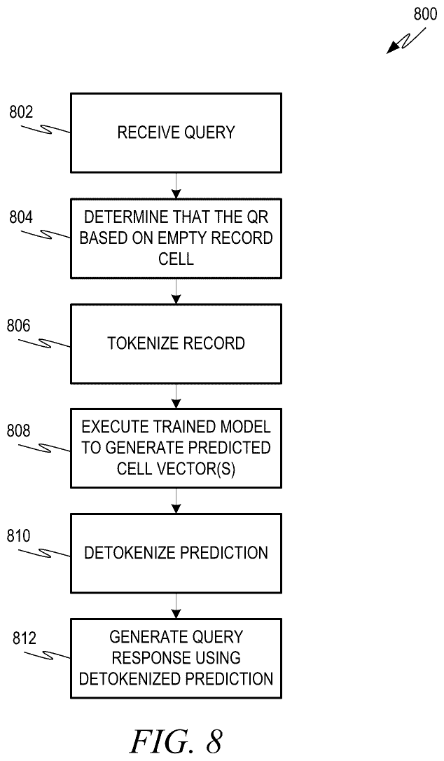

FIG. 8 is a flowchart showing one example of a process flow 800 that may be executed by the database management application 118 of FIG. 1 to respond to a query using the computerized model 120 of FIG. 1. The process flow 800 may be executed after training of the computerized model 120. At operation 802, the database management application 118 may receive a query. The query may be received directly from a user 126, 128 and/or may be received from an ERP application 114, 116. When the query is received from an ERP application 114, 116, it may be in response to interactions between a user 126, 128 and the respective ERP application 114, 116.

At operation 804, the database management application 118 may determine that a response to the query includes or is based on at least one empty cell of a record. For example, the database management application 118 may execute the query and determine that at least a portion of the response includes one or more unpopulated or empty record cells.

At operation 806, the database management application 118 may tokenize the record having an empty cell to generate a tokenized record. If the response to the query depends on more than one record having one or more empty cells, then the database management application 118 may tokenize each record.

At operation 808, the database management application 118 may prompt execution of the computerized model 120 to generate a prediction of the one or more empty record cells. If multiple records with empty cells were determined at operation 804, then the computerized model 120 may be executed multiple times, once for each record. The result of executing the model may be a prediction of a cell vector for each empty cell. In some examples, the computerized model 120 is configured to generate a predicted cell vector of each data type for each empty cell. The database management application 118 may select a predicted cell vector based on the data type associated with the column of the empty cell.

At operation 810, the database management application 118 may detokenize the prediction or predictions generated at operation 808. This may include converting the predicted cell vector or vectors to an appropriate data format such as a numerical value, a date, and/or text. At operation 812, the database management application 118 may generate a response to the query using the de-tokenized prediction or predictions generated at operation 810.

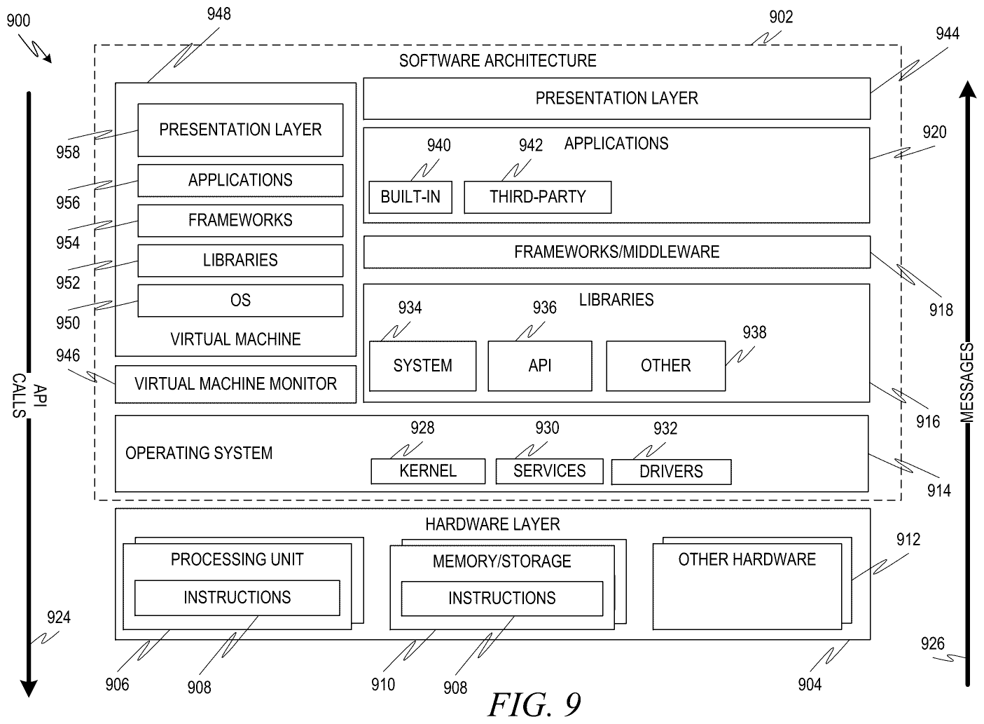

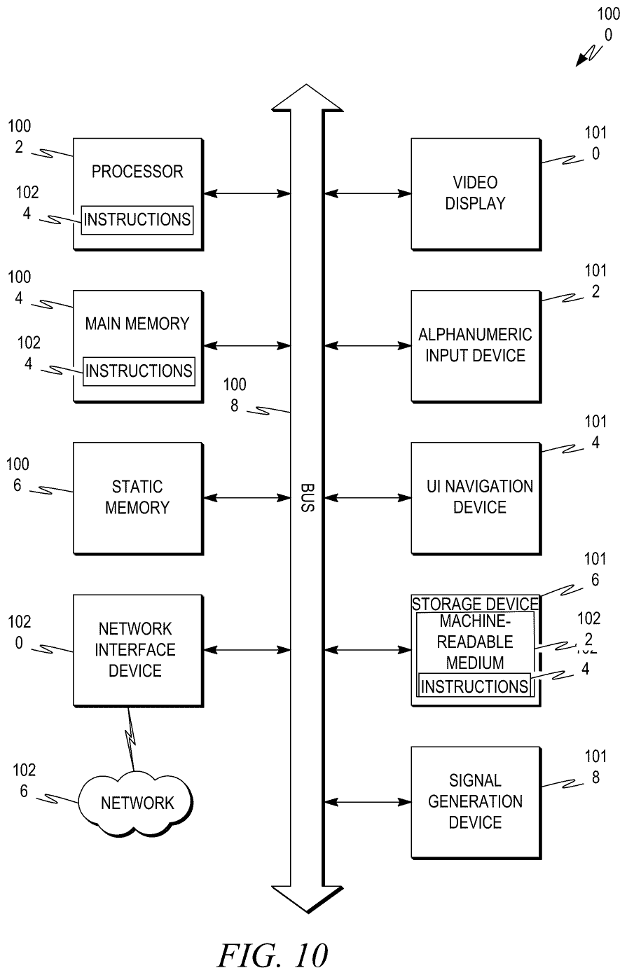

FIG. 9 is a block diagram 900 showing one example of a software architecture 902 for a computing device. The architecture 902 may be used in conjunction with various hardware architectures, for example, as described herein. FIG. 9 is merely a non-limiting example of a software architecture and many other architectures may be implemented to facilitate the functionality described herein. A representative hardware layer 904 is illustrated and can represent, for example, any of the above referenced computing devices. In some examples, the hardware layer 904 may be implemented according to the architecture of the computer system of FIG. 10.

The representative hardware layer 904 comprises one or more processing units 906 having associated executable instructions 908. Executable instructions 908 represent the executable instructions of the software architecture 902, including implementation of the methods, modules, subsystems, and components, and so forth described herein and may also include memory and/or storage modules 910, which also have executable instructions 908. Hardware layer 904 may also comprise other hardware as indicated by other hardware 912 which represents any other hardware of the hardware layer 904, such as the other hardware illustrated as part of the architecture 902.

In the example architecture of FIG. 9, the software architecture 902 may be conceptualized as a stack of layers where each layer provides particular functionality. For example, the software architecture 902 may include layers such as an operating system 914, libraries 916, middleware layer 918, applications 920, and presentation layer 944. Operationally, the applications 920 and/or other components within the layers may invoke API calls 924 through the software stack and access a response, returned values, and so forth illustrated as messages 926 in response to the API calls 924. The layers illustrated are representative in nature and not all software architectures have all layers. For example, some mobile and/or special purpose operating systems may not provide a middleware layer 918, while others may provide such a layer. Other software architectures may include additional and/or different layers.

The operating system 914 may manage hardware resources and provide common services. The operating system 914 may include, for example, a kernel 928, services 930, and drivers 932. The kernel 928 may act as an abstraction layer between the hardware and the other software layers. For example, the kernel 928 may be responsible for memory management, processor management (e.g., scheduling), component management, networking, security settings, and so on. The services 930 may provide other common services for the other software layers. In some examples, the services 930 include an interrupt service. The interrupt service may detect the receipt of an interrupt and, in response, cause the architecture 902 to pause its current processing and execute an interrupt service routine (ISR) when an interrupt is accessed.

The drivers 932 may be responsible for controlling and/or interfacing with the underlying hardware. For instance, the drivers 932 may include display drivers, camera drivers, Bluetooth® drivers, flash memory drivers, serial communication drivers (e.g., Universal Serial Bus [USB] drivers), Wi-Fi® drivers, NFC drivers, audio drivers, power management drivers, and so forth depending on the hardware configuration.

The libraries 916 may provide a common infrastructure that may be utilized by the applications 920 and/or other components and/or layers. The libraries 916 typically provide functionality that allows other software modules to perform tasks in an easier fashion than to interface directly with the underlying operating system 914 functionality (e.g., kernel 928, services 930 and/or drivers 932). The libraries 916 may include system 934 libraries (e.g., C standard library) that may provide functions such as memory allocation functions, string manipulation functions, mathematic functions, and the like. In addition, the libraries 916 may include API libraries 936 such as media libraries (e.g., libraries to support presentation and manipulation of various media format such as MPEG4, H.264, MP3, AAC, AMR, JPG, PNG), graphics libraries (e.g., an OpenGL framework that may be used to render 2D and 3D in a graphic content on a display), database libraries (e.g., SQLite that may provide various relational database functions), web libraries (e.g., WebKit that may provide web browsing functionality), and the like. The libraries 916 may also include a wide variety of other libraries 938 to provide many other APIs to the applications 920 and other software components/modules.

The middleware layer 918 (also sometimes referred to as frameworks) may provide a higher-level common infrastructure that may be utilized by the applications 920 and/or other software components/modules. For example, the middleware layer 918 may provide various graphic user interface (GUI) functions, high-level resource management, high-level location services, and so forth. The middleware layer 918 may provide a broad spectrum of other APIs that may be utilized by the applications 920 and/or other software components/modules, some of which may be specific to a particular operating system and/or platform.

The applications 920 include built-in applications 940 and/or third-party applications 942. Examples of representative built-in applications 940 may include, but are not limited to, a contacts application, a browser application, a book reader application, a location application, a media application, a messaging application, and/or a game application. Third-party applications 942 may include any of the built-in applications 940 as well as a broad assortment of other applications. In a specific example, the third-party application 942 (e.g., an application developed using the Android™ or iOS™ software development kit (SDK) by an entity other than the vendor of the particular platform) may be mobile software running on a mobile operating system such as iOS™, Android™, Windows® Phone, or other mobile computing device operating systems. In this example, the third-party application 942 may invoke the API calls 924 provided by the mobile operating system such as operating system 914 to facilitate functionality described herein.

The applications 920 may utilize built-in operating system functions (e.g., kernel 928, services 930 and/or drivers 932), libraries (e.g., system 934, API libraries 936, and other libraries 938), and middleware layer 918 to create user interfaces to interact with users of the system. Alternatively, or additionally, in some systems interactions with a user may occur through a presentation layer, such as presentation layer 944. In these systems, the application/module “logic” can be separated from the aspects of the application/module that interact with a user.

Some software architectures utilize virtual machines. In the example of FIG. 9, this is illustrated by virtual machine 948. A virtual machine creates a software environment where applications/modules can execute as if they were executing on a hardware computing device. A virtual machine is hosted by a host operating system (operating system 914) and typically, although not always, has a virtual machine monitor 946, which manages the operation of the virtual machine as well as the interface with the host operating system (i.e., operating system 914). A software architecture executes within the virtual machine such as an operating system 950, libraries 952, frameworks/middleware 954, applications 956 and/or presentation layer 958. These layers of software architecture executing within the virtual machine 948 can be the same as corresponding layers previously described or may be different.

### Modules, Components and Logic

Certain embodiments are described herein as including logic or a number of components, modules, or mechanisms. Modules may constitute either software modules (e.g., code embodied [1] on a non-transitory machine-readable medium or [2] in a transmission signal) or hardware-implemented modules. A hardware-implemented module is a tangible unit capable of performing certain operations and may be configured or arranged in a certain manner. In example embodiments, one or more computer systems (e.g., a standalone, client, or server computer system) or one or more hardware processors may be configured by software (e.g., an application or application portion) as a hardware-implemented module that operates to perform certain operations as described herein.

In various embodiments, a hardware-implemented module may be implemented mechanically or electronically. For example, a hardware-implemented module may comprise dedicated circuitry or logic that is permanently configured (e.g., as a special-purpose processor, such as a field programmable gate array [FPGA] or an application-specific integrated circuit [ASIC]) to perform certain operations. A hardware-implemented module may also comprise programmable logic or circuitry (e.g., as encompassed within a general-purpose processor or another programmable processor) that is temporarily configured by software to perform certain operations. It will be appreciated that the decision to implement a hardware-implemented module mechanically, in dedicated and permanently configured circuitry, or in temporarily configured circuitry (e.g., configured by software) may be driven by cost and time considerations.

Accordingly, the term “hardware-implemented module” should be understood to encompass a tangible entity, be that an entity that is physically constructed, permanently configured (e.g., hardwired), or temporarily or transitorily configured (e.g., programmed) to operate in a certain manner and/or to perform certain operations described herein. Considering embodiments in which hardware-implemented modules are temporarily configured (e.g., programmed), each of the hardware-implemented modules need not be configured or instantiated at any one instance in time. For example, where the hardware-implemented modules comprise a general-purpose processor configured using software, the general-purpose processor may be configured as respective different hardware-implemented modules at different times. Software may accordingly configure a processor, for example, to constitute a particular hardware-implemented module at one instance of time and to constitute a different hardware-implemented module at a different instance of time.

Hardware-implemented modules can provide information to, and receive information from, other hardware-implemented modules. Accordingly, the described hardware-implemented modules may be regarded as being communicatively coupled. Where multiple of such hardware-implemented modules exist contemporaneously, communications may be achieved through signal transmission (e.g., over appropriate circuits and buses that connect the hardware-implemented modules). In embodiments in which multiple hardware-implemented modules are configured or instantiated at different times, communications between such hardware-implemented modules may be achieved, for example, through the storage and retrieval of information in memory structures to which the multiple hardware-implemented modules have access. For example, one hardware-implemented module may perform an operation, and store the output of that operation in a memory device to which it is communicatively coupled. A further hardware-implemented module may then, at a later time, access the memory device to retrieve and process the stored output. Hardware-implemented modules may also initiate communications with input or output devices, and can operate on a resource (e.g., a collection of information).

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some example embodiments, comprise processor-implemented modules.

Similarly, the methods described herein may be at least partially processor-implemented. For example, at least some of the operations of a method may be performed by one or more processors or processor-implemented modules. The performance of certain of the operations may be distributed among the one or more processors, not only residing within a single machine, but deployed across a number of machines. In some example embodiments, the processor or processors may be located in a single location (e.g., within a home environment, an office environment, or a server farm), while in other embodiments the processors may be distributed across a number of locations.

The one or more processors may also operate to support performance of the relevant operations in a “cloud computing” environment or as a “software as a service” (SaaS). For example, at least some of the operations may be performed by a group of computers (as examples of machines including processors), these operations being accessible via a network (e.g., the Internet) and via one or more appropriate interfaces (e.g., APIs).

### Electronic Apparatus and System

Example embodiments may be implemented in digital electronic circuitry, or in computer hardware, firmware, or software, or in combinations of them. Example embodiments may be implemented using a computer program product, e.g., a computer program tangibly embodied in an information carrier, e.g., in a machine-readable medium for execution by, or to control the operation of, data processing apparatus, e.g., a programmable processor, a computer, or multiple computers.

A computer program can be written in any form of programming language, including compiled or interpreted languages, and it can be deployed in any form, including as a standalone program or as a module, subroutine, or other unit suitable for use in a computing environment. A computer program can be deployed to be executed on one computer or on multiple computers at one site or distributed across multiple sites and interconnected by a communication network.

In example embodiments, operations may be performed by one or more programmable processors executing a computer program to perform functions by operating on input data and generating output. Method operations can also be performed by, and apparatus of example embodiments may be implemented as, special purpose logic circuitry, e.g., an FPGA or an ASIC.

The computing system can include clients and servers. A client and server are generally remote from each other and typically interact through a communication network. The relationship of client and server arises by virtue of computer programs running on the respective computers and having a client-server relationship to each other. In embodiments deploying a programmable computing system, it will be appreciated that both hardware and software architectures merit consideration. Specifically, it will be appreciated that the choice of whether to implement certain functionality in permanently configured hardware (e.g., an ASIC), in temporarily configured hardware (e.g., a combination of software and a programmable processor), or in a combination of permanently and temporarily configured hardware may be a design choice. Below are set out hardware (e.g., machine) and software architectures that may be deployed, in various example embodiments.

### Example Machine Architecture and Machine-Readable Medium

FIG. 10 is a block diagram of a machine in the example form of a computer system 1000 within which instructions 1024 may be executed for causing the machine to perform any one or more of the methodologies discussed herein. In alternative embodiments, the machine operates as a standalone device or may be connected (e.g., networked) to other machines. In a networked deployment, the machine may operate in the capacity of a server or a client machine in server-client network environment, or as a peer machine in a peer-to-peer (or distributed) network environment. The machine may be a personal computer (PC), a tablet PC, a set-top box (STB), a personal digital assistant (PDA), a cellular telephone, a web appliance, a network router, switch, or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein.

The example computer system 1000 includes a processor 1002 (e.g., a central processing unit [CPU], a graphics processing unit [GPU], or both), a main memory 1004, and a static memory 1006, which communicate with each other via a bus 1008. The computer system 1000 may further include a video display unit 1010 (e.g., a liquid crystal display [LCD] or a cathode ray tube [CRT]). The computer system 1000 also includes an alphanumeric input device 1012 (e.g., a keyboard or a touch-sensitive display screen), a user interface navigation (or cursor control) device 1014 (e.g., a mouse), a disk drive unit 1016, a signal generation device 1018 (e.g., a speaker), and a network interface device 1020.

### Machine-Readable Medium

The disk drive unit 1016 includes a machine-readable medium 1022 on which is stored one or more sets of data structures and instructions 1024 (e.g., software) embodying or utilized by any one or more of the methodologies or functions described herein. The instructions 1024 may also reside, completely or at least partially, within the main memory 1004 and/or within the processor 1002 during execution thereof by the computer system 1000, with the main memory 1004 and the processor 1002 also constituting machine-readable media 1022.

While the machine-readable medium 1022 is shown in an example embodiment to be a single medium, the term “machine-readable medium” may include a single medium or multiple media (e.g., a centralized or distributed database, and/or associated caches and servers) that store the one or more instructions 1024 or data structures. The term “machine-readable medium” shall also be taken to include any tangible medium that is capable of storing, encoding, or carrying instructions 1024 for execution by the machine and that cause the machine to perform any one or more of the methodologies of the present disclosure, or that is capable of storing, encoding, or carrying data structures utilized by or associated with such instructions 1024. The term “machine-readable medium” shall accordingly be taken to include, but not be limited to, solid-state memories, and optical and magnetic media. Specific examples of machine-readable media 1022 include non-volatile memory, including by way of example semiconductor memory devices, e.g., erasable programmable read-only memory (EPROM), electrically erasable programmable read-only memory (EEPROM), and flash memory devices; magnetic disks such as internal hard disks and removable disks; magneto-optical disks; and CD-ROM and DVD-ROM disks.

### Transmission Medium

The instructions 1024 may further be transmitted or received over a communications network 1026 using a transmission medium. The instructions 1024 may be transmitted using the network interface device 1020 and any one of a number of well-known transfer protocols (e.g., HTTP). Examples of communication networks include a local area network (LAN), a wide area network (WAN), the Internet, mobile telephone networks, plain old telephone (POTS) networks, and wireless data networks (e.g., WiFi and WiMax networks). The term “transmission medium” shall be taken to include any intangible medium that is capable of storing, encoding, or carrying instructions 1024 for execution by the machine, and includes digital or analog communications signals or other intangible media to facilitate communication of such software.

Although an embodiment has been described with reference to specific example embodiments, it will be evident that various modifications and changes may be made to these embodiments without departing from the broader spirit and scope of the disclosure. Accordingly, the specification and drawings are to be regarded in an illustrative rather than a restrictive sense. The accompanying drawings that form a part hereof show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

1. A system for using a computerized model, the system comprising at least one processor programmed to perform operations comprising:
accessing training data, the training data comprising a plurality of tables, a first table of the plurality of tables comprising a plurality of records, a first record of the plurality of records comprising a first plurality of cells;
tokenizing the first plurality of cells to generate a first tokenized record comprising a first plurality of cell vectors;
masking a masked portion of the first plurality of cell vectors to generate a first masked tokenized record;
executing the computerized model using the first masked tokenized record to generate a prediction of the masked portion of the first plurality of cells; determining an error based at least in part on the prediction of the masked portion of the first plurality of cells; and
modifying the computerized model based on the error.

2. The system of claim 1, the first plurality of cell vectors comprising a first cell vector corresponding to a first cell of the first plurality of cells, the first cell vector being based at least in part on a content of the first cell and on column data describing a column of the first table that corresponds to the first cell.

3. The system of claim 2, the first cell comprising text data, the tokenizing comprising executing a pre-trained computerized model using the text data, the first cell vector being based at least in part on a result of the executing of the pre-trained computerized model.

4. The system of claim 3, the executing of the computerized model comprising generating a predicted text cell vector for the first cell, a predicted date cell vector for the first cell, and a predicted numerical cell vector for the first cell, the operations further comprising:
determining that a column associated with the first cell comprises text data; and
selecting the predicted text cell vector for the prediction of the masked portion of the first plurality of cell vectors.

5. The system of claim 1, the first plurality of cell vectors comprising a second cell vector corresponding to a second cell of the first plurality of cells, the second cell comprising timestamp data, and the second cell vector being based at least in part on a day indicated by the timestamp data, a month indicated by the timestamp data, and a year indicated by the timestamp data.

6. The system of claim 5, the second cell vector also being based at least in part on date metadata describing timestamp data.

7. The system of claim 1, the first plurality of cell vectors comprising a third cell vector corresponding to a third cell of the first plurality of cells, the third cell comprising numerical data, the tokenizing of the numerical data being based at least in part on a factor associated with a value of the numerical data, an exponent associated with the value of the numerical data, and sign data associated with the value of the numerical data.

8. The system of claim 1, the masked portion of the first plurality of cell vectors comprising between about 10% and about 80% of the first plurality of cell vectors.

9. The system of claim 1, the operations further comprising randomly selecting the masked portion of the first plurality of cell vectors.

10. The system of claim 1, the operations further comprising:
masking a masked portion of a second plurality of cell vectors associated with a second record of the plurality of records to generate a second masked tokenized record generated from a second record of the plurality of records, the masked portion of the second plurality of cell vectors being equivalent to the masked portion of the first plurality of cell vectors; and
executing the computerized model using the second masked tokenized record to generate a prediction of the masked portion of the second plurality of cell vectors, the error also being based at least in part on the prediction of the masked portion of the second plurality of cell vectors.

11. The system of claim 10, the operations further comprising:
masking a masked portion of a third plurality of cell vectors associated with a third record of the plurality of records to generate a third masked tokenized record generated from a third record of the plurality of records, the masked portion of the third plurality of cell vectors being different than the masked portion of the first plurality of cell vectors; and
executing the computerized model using the third masked tokenized record to generate a prediction of the masked portion of the third plurality of cell vectors, the error also being based at least in part on the prediction of the masked portion of the third plurality of cell vectors.

12. The system of claim 1, the operations further comprising:
receiving a query, a response to the query being based at least in part on a cell value of a cell of a first database record, the cell of the first database record being empty at the database;
executing the computerized model using the first database record to generate a predicted cell value for the cell; and
using the predicted cell value to generate a query response.

13. A method of using a computerized model, the method comprising:
accessing training data, the training data comprising a plurality of tables, a first table of the plurality of tables comprising a plurality of records, a first record of the plurality of records comprising a first plurality of cells;
tokenizing the first plurality of cells to generate a first tokenized record comprising a first plurality of cell vectors;
masking a masked portion of the first plurality of cell vectors to generate a first masked tokenized record;
executing the computerized model using the first masked tokenized record to generate a prediction of the masked portion of the first plurality of cells;
determining an error based at least in part on the prediction of the masked portion of the first plurality of cells; and
modifying the computerized model based on the error.

14. The method of claim 13, the first plurality of cell vectors comprising a first cell vector corresponding to a first cell of the first plurality of cells, the first cell vector being based at least in part on a content of the first cell and on column data describing a column of the first table that corresponds to the first cell.

15. The method of claim 14, the first cell comprising text data, the tokenizing comprising executing a pre-trained computerized model using the text data, the first cell vector being based at least in part on a result of the executing of the pre-trained computerized model.

16. The method of claim 15, the executing of the computerized model comprising:
generating a predicted text cell vector for the first cell, a predicted date cell vector for the first cell, and a predicted numerical cell vector for the first cell, the method further comprising:
determining that a column associated with the first cell comprises text data; and
selecting the predicted text cell vector for the prediction of the masked portion of the first plurality of cell vectors.

17. The method of claim 13, the first plurality of cell vectors comprising a second cell vector corresponding to a second cell of the first plurality of cells, the second cell comprising timestamp data, and the second cell vector being based at least in part on a day indicated by the timestamp data, a month indicated by the timestamp data, and a year indicated by the timestamp data.

18. The method of claim 13, the first plurality of cell vectors comprising a third cell vector corresponding to a third cell of the first plurality of cells, the third cell comprising numerical data, the tokenizing of the numerical data being based at least in part on a factor associated with a value of the numerical data, an exponent associated with the value of the numerical data, and sign data associated with the value of the numerical data.

19. The method of claim 13, further comprising:
masking a masked portion of a second plurality of cell vectors associated with a second record of the plurality of records to generate a second masked tokenized record generated from a second record of the plurality of records, the masked portion of the second plurality of cell vectors being equivalent to the masked portion of the first plurality of cell vectors; and
executing the computerized model using the second masked tokenized record to generate a prediction of the masked portion of the second plurality of cell vectors, the error also being based at least in part on the prediction of the masked portion of the second plurality of cell vectors.

20. A non-transitory machine-readable medium comprising instructions thereon that, when executed by at least one processor, because the at least one processor to perform operations comprising:
accessing training data, the training data comprising a plurality of tables, a first table of the plurality of tables comprising a plurality of records, a first record of the plurality of records comprising a first plurality of cells;
tokenizing the first plurality of cells to generate a first tokenized record comprising a first plurality of cell vectors;
masking a masked portion of the first plurality of cell vectors to generate a first masked tokenized record;
executing a computerized model using the first masked tokenized record to generate a prediction of the masked portion of the first plurality of cells;
determining an error based at least in part on the prediction of the masked portion of the first plurality of cells; and
modifying the computerized model based on the error.
